(19) United States
(12) Patent Application Publication
(10) Pub. No.: US 2013/0321060 A1
(43) Pub. Date: Dec. 5, 2013

(54) INPUT BUFFER CIRCUIT AND SEMICONDUCTOR DEVICE

(71) Applicant: FUJITSU SEMICONDUCTOR LIMITED, Yokohama-shi (JP)

(72) Inventors: Junko NAKAMOTO, Tachikawa (JP); Hideki ISHIDA, Hachioji (JP)

(21) Appl. No.: 13/904,833

(22) Filed: May 29, 2013

(30) Foreign Application Priority Data
Jun. 4, 2012 (JP) 2012-127316

(51) Int. Cl. H03K 17/30

(52) U.S. Cl. CPC H03K 17/302
USPC 327/333

(57) ABSTRACT

A drain or a source of a transistor which receives an input signal at a gate is connected to a back gate of the transistor. A voltage changing circuit portion changes voltage applied to the drain or the source in accordance with a change in potential level of the input signal so that a potential difference between the gate and the drain or the source is lower than or equal to breakdown voltage of the transistor.

### CROSS-REFERENCE TO RELATED APPLICATION

This application is based upon and claims the benefit of priority of the prior Japanese Patent Application No. 2012-127316, filed on Jun. 4, 2012, the entire contents of which are incorporated herein by reference.

### FIELD

The embodiments discussed herein are related to an input buffer circuit and a semiconductor device.

### BACKGROUND

As semiconductor devices, such as LSIs (Large-Scale Integrated circuits), become minuter, the breakdown voltage of transistors decreases. As a result, a low power supply voltage of, for example, 1.8 V or 1 V is used in semiconductor devices.

However, voltage inputted to semiconductor devices remains high. In many cases, for example, a potential level at an interface in transmission between chips is 3.3 V or 5 V.

The following input buffer circuit is proposed. In order to reduce the potential level of an input signal, an n-channel MOSFET (Metal-Oxide Semiconductor Field Effect Transistor) whose breakdown voltage is comparatively high is connected between an input terminal and an internal circuit. By doing so, the internal circuit is protected.

Japanese Laid-open Patent Publication No. 11-251898

Japanese Laid-open Patent Publication No. 2006-279569

A decrease in the breakdown voltage of transistors makes it difficult for conventional input buffer circuits to accept an input signal whose potential level is high. If there is a great potential difference between power supply voltage and the potential level of an input signal, then a low breakdown voltage transistor which accepts the input signal breaks down.

### SUMMARY

According to an aspect, there is provided an input buffer circuit including: a first transistor configured to receive an input signal at a first gate, a first drain or first source of the first transistor being connected to a first back gate of the first transistor; and a voltage changing circuit portion configured to change a first voltage applied to the first drain or the first source in accordance with a change in potential level of the input signal so that a potential difference between the first gate and the first drain or the first source is lower than or equal to breakdown voltage of the first transistor.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an example of an input buffer circuit according to a first embodiment;

FIG. 2 is an example of an input buffer circuit according to a second embodiment;

FIG. 3 is examples of the waveforms of the voltage of a signal inputted to an input buffer circuit and voltage at nodes n1 and n2 in the input buffer circuit;

FIG. 4 is examples of the waveforms of the voltage of the signal inputted to the input buffer circuit and voltage at a node n3 in the input buffer circuit; and

FIG. 5 is an example of a semiconductor device.

### DESCRIPTION OF EMBODIMENTS

Embodiments will now be described with reference to the accompanying drawings, wherein like reference numerals refer to like elements throughout.

### First Embodiment

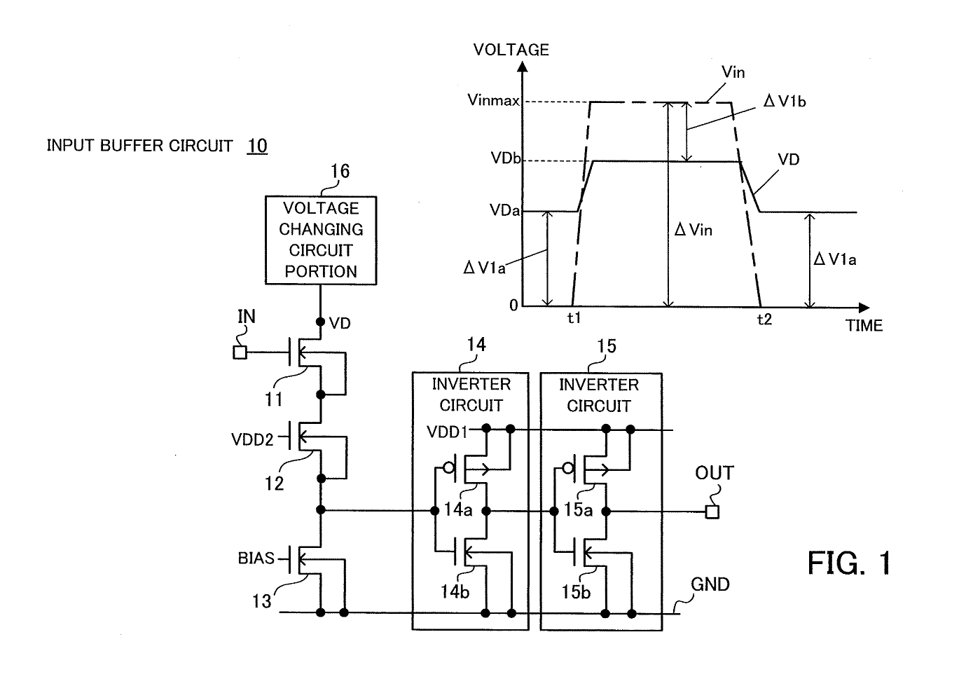

FIG. 1 is an example of an input buffer circuit according to a first embodiment.

An input buffer circuit 10 includes transistors 11, 12, and 13, inverter circuits 14 and 15, and a voltage changing circuit portion 16.

In the example of FIG. 1, each of the transistors 11 through 13 is an n-channel MOSFET.

A gate of the transistor 11 is connected to an input terminal IN. The transistor 11 receives at the gate an input signal which changes by potential difference ΔVin. A drain of the transistor 11 is connected to the voltage changing circuit portion 16 and a back gate of the transistor 11 is connected to a source of the transistor 11.

A drain of the transistor 12 is connected to the source of the transistor 11. A source of the transistor 12 is connected to a back gate of the transistor 12 and a drain of the transistor 13. A source and a back gate of the transistor 13 are connected to a reference power supply line GND.

A node between the source of the transistor 12 and the drain of the transistor 13 is connected to a circuit (inverter circuit 14, in the example of FIG. 1) at a subsequent stage.

Furthermore, power supply voltage VDD2, for example, is applied to a gate of the transistor 12 as gate voltage. Bias voltage BIAS is applied to a gate of the transistor 13 as gate voltage. By applying such gate voltage, the transistors 12 and 13 go into an ON state.

The power supply voltage VDD2 is lower than or equal to breakdown voltage of the transistor 12. The bias voltage BIAS is lower than or equal to breakdown voltage of the transistor 13.

The inverter circuit 14 includes a transistor 14a, which is a p-channel MOSFET, and a transistor 14b, which is an n-channel MOSFET. The inverter circuit 15 includes a transistor 15a, which is a p-channel MOSFET, and a transistor 15b, which is an n-channel MOSFET. That is to say, each of the inverter circuits 14 and 15 has a CMOS (Complementary MOS) structure. The inverter circuits 14 and 15 are driven by power supply voltage VDD1. In the example of FIG. 1, the back inverter circuit 15 is connected to an output terminal OUT.

In the example of FIG. 1, the voltage changing circuit portion 16 is connected to the drain of the transistor 11. The voltage changing circuit portion 16 changes voltage applied to the drain or the source of the transistor 11 according to a change in the potential level of an input signal so as to make the potential difference between the gate and the drain or the source lower than or equal to breakdown voltage of the transistor 11.

FIG. 1 indicates the waveforms of examples of drain voltage VD of the transistor 11 and voltage Vin of an input signal. A horizontal axis indicates time and a vertical axis indicates voltage. When the voltage Vin of the input signal is 0 V, the voltage changing circuit portion 16 applies voltage VDa which makes potential difference ΔV1a between the gate and the drain lower than or equal to the breakdown voltage of the transistor 11 to the drain of the transistor 11 as the drain voltage VD.

When the voltage Vin of the input signal rises toward voltage Vinmax at timing t1, the transistor 11 goes into an ON state. At this time the voltage changing circuit portion 16 raises the drain voltage VD to prevent potential difference ΔV1b between the gate and the drain from exceeding the breakdown voltage. When the voltage Vin of the input signal rises, the transistor 11 goes into an ON state. Accordingly, source voltage becomes a value corresponding to the drain voltage VD. This makes it possible to prevent potential difference between the gate and the source from exceeding the breakdown voltage (not indicated). Furthermore, the back gate of the transistor 11 is connected to the source of the transistor 11. Therefore, it is possible to prevent potential difference between the gate and the back gate from exceeding the breakdown voltage (not indicated).

When the voltage Vin falls from the voltage Vinmax toward 0 V at timing t2, the transistor 11 goes into an OFF state. At this time the voltage changing circuit portion 16 decreases the drain voltage VD to the voltage VDa to prevent potential difference between the gate and the drain from exceeding the breakdown voltage.

As has been described, the voltage changing circuit portion 16 changes voltage applied to the drain or the source of the transistor 11 according to a change in the potential level of an input signal so as to make the potential difference between the gate and the drain or the source lower than or equal to the breakdown voltage of the transistor 11. This prevents a transistor whose breakdown voltage is low from breaking down.

Furthermore, the gate voltage of the transistor 12 is made lower than or equal to the breakdown voltage of the transistor 12. This prevents the transistor 12 from breaking down. In addition, the bias voltage BIAS is made lower than or equal to the breakdown voltage of the transistor 13. This prevents the transistor 13 from breaking down.

Furthermore, control is exercised so as to make source voltage of the transistor 12 corresponding to the potential level of a signal inputted to the inverter circuit 14 lower than or equal to the gate voltage (power supply voltage VDD2) of the transistor 12. This prevents the transistor 14a or 14b from breaking down. As a result, the potential level of a signal outputted from the inverter circuit 14 is low. This prevents a transistor included in the inverter circuit 15 or a circuit connected to the output terminal OUT from breaking down.

In the above description each of the transistors 11 through 13 is an n-channel MOSFET. However, each of the transistors 11 through 13 may be a p-channel MOSFET. In that case, the drain of the transistor 11 is connected to the back gate. The voltage changing circuit portion 16 changes voltage applied to the drain or the source of the transistor 11 according to a change in the potential level of an input signal so as to make the potential difference between the gate of the transistor 11 and the drain or source of the transistor 11 lower than or equal to breakdown voltage of the transistor 11.

### Second Embodiment

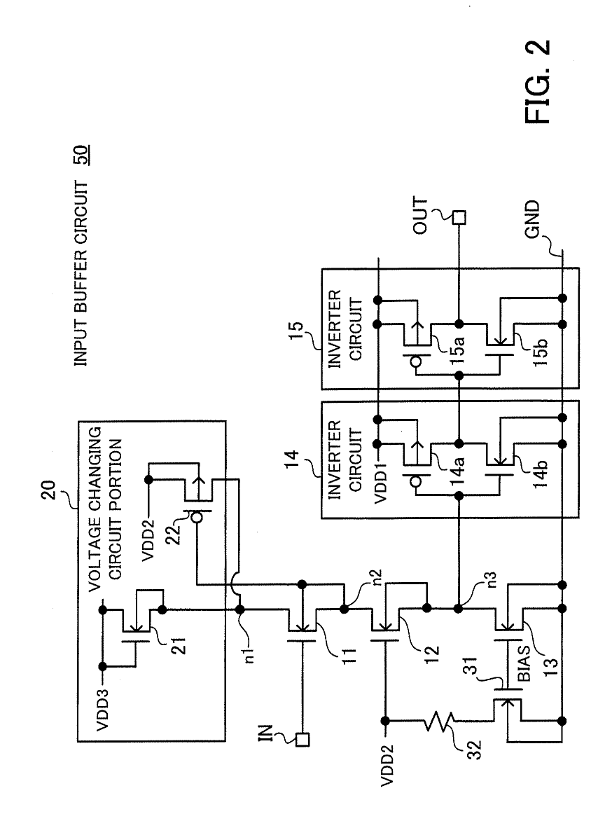

FIG. 2 is an example of an input buffer circuit according to a second embodiment.

Components which are the same as those included in the input buffer circuit 10 illustrated in FIG. 1 are marked with the same numerals.

An input buffer circuit 50 according to a second embodiment is driven by three power supply voltages VDD1, VDD2, and VDD3, where VDD3>VDD2>VDD1.

The input buffer circuit 50 includes a voltage changing circuit portion 20 including transistors 21 and 22, a transistor 31, and a resistor 32.

With the voltage changing circuit portion 20 illustrated in FIG. 2, the transistor 21 is an n-channel MOSFET and the transistor 22 is a p-channel MOSFET.

The power supply voltage VDD3 is applied to a drain and a gate of the transistor 21 and a source of the transistor 21 is connected to a drain of a transistor 11. In addition, a back gate of the transistor 21 is connected to the source of the transistor 21.

The power supply voltage VDD2 is applied to a source and a back gate of the transistor 22. A drain of the transistor 22 is connected to a node n1 between the source of the transistor 21 and the drain of the transistor 11. Furthermore, a gate of the transistor 22 is connected to a back gate and a source of the transistor 11 (node n2).

The transistor 31 is an n-channel MOSFET. The power supply voltage VDD2 is applied to a drain of the transistor 31 via the resistor 32. A source and a back gate of the transistor 31 are connected to a reference power supply line GND. Furthermore, a gate of the transistor 31 is connected to a gate of a transistor 13. The transistor 31 is in an ON state by bias voltage BIAS.

In the above input buffer circuit 50 voltage Vn2 at the node n2 is given by

Vn2=Vin−Vthn1 (Vn2≦Vn1 (voltage at node n1)) (1)

where Vthn1 is threshold voltage of the transistor 11.

Furthermore, when VDD2−Vthp1≧Vn2, voltage Vn1 at the node n1 is given by

Vn1=VDD2 (2)
where Vthp1 is threshold voltage of the transistor 22.

When VDD2−Vthp1<Vn2, voltage Vn1 at the node n1 is given by

Vn1=VDD3−Vthn2 (3)
where Vthn2 is threshold voltage of the transistor 21.

In addition, it is assumed that Vthp1≈Vthn1. Then when Vin≦VDD2, voltage Vn1 and voltage Vn2 are given by:

Vn1=VDD2 (4)

Vn2=Vin−Vthn1 (≦VDD2) (5)

When Vin≧VDD2, voltage Vn1 and voltage Vn2 are given by:

Vn1=VDD3−Vthn2 (6)

Vn2=Vn1−Vthn1 (7)
Therefore, VDD2−Vthn1≦Vn2≦VDD3−Vthn2.

An example of the operation of the input buffer circuit 50 will now be described.

It is assumed that each of the transistor 11, transistors 12, 13, 14a, 14b, 15a, and 15b, and the transistors 21, 22, and 31 included in the input buffer circuit 50 is a 1.8-volt transistor (breakdown voltage is lower than or equal to 2 V). In addition, it is assumed that power supply voltage VDD1=1.0 V, that power supply voltage VDD2=1.8 V, and that power supply voltage VDD3=3.3 V. Furthermore, it is assumed that the size of the transistor 22 is sufficiently large compared with that of the transistor 21. Moreover, it is assumed that threshold voltage of each transistor is, for example, about 0.1 V.

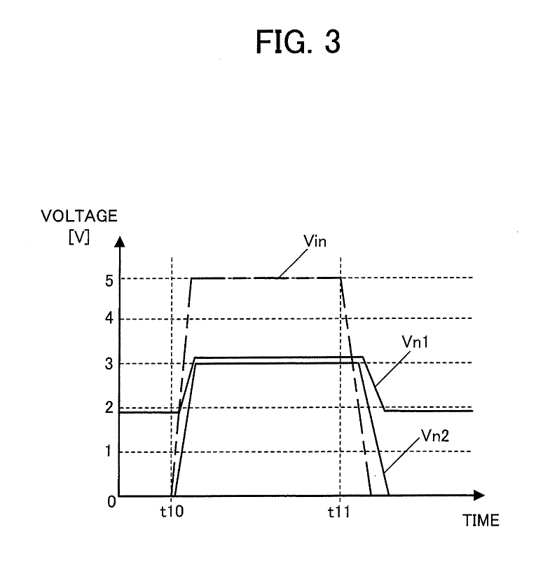

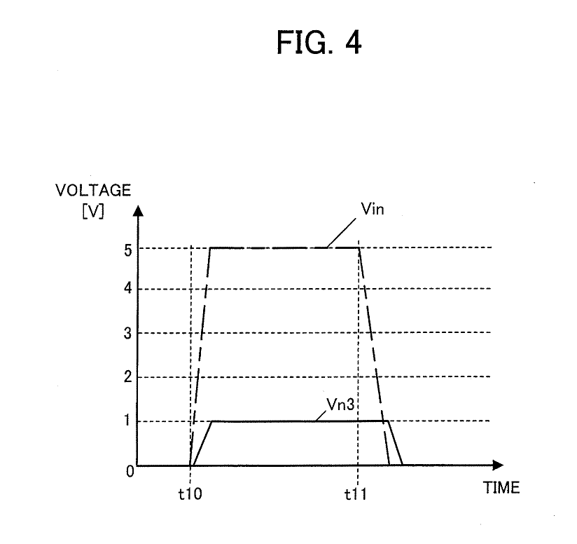

FIGS. 3 and 4 are examples of the waveforms of the voltage of a signal inputted to the input buffer circuit 50 and voltage at each node. In each of FIGS. 3 and 4, a horizontal axis indicates time and a vertical axis indicates voltage (V).

FIG. 3 indicates the waveforms of voltage Vin of a signal inputted to the input buffer circuit 50, voltage Vn1 at the node n1, and voltage Vn2 at the node n2. FIG. 4 indicates the waveforms of the voltage Vin and voltage Vn3 at the node n3 (node between a source of the transistor 12 and a drain of the transistor 13).

When the voltage Vin of the signal inputted to the input buffer circuit 50 is 0 V before or at timing t10, the transistor 11 is in an OFF state. At this time the transistors 12 and 13 are in an ON state, so the voltage Vn2 at the node n2 is close to the potential (0 V, for example) of the reference power supply line GND. Accordingly, the transistor 22, which is a p-channel MOSFET, goes into an ON state. By applying the power supply voltage VDD3, the transistor 21 remains an ON state. However, the size of the transistor 22 is sufficiently large compared with that of the transistor 21. Therefore, as indicated in FIG. 3, the voltage Vn1 at the node n1 becomes approximately equal to the power supply voltage VDD2 (=1.8 V) when the transistor 22 goes into an ON state.

As a result, the potential difference between a gate and the source of the transistor 11, the potential difference between the gate and the drain of the transistor 11, and the potential difference between the gate and the back gate of the transistor 11 is smaller than or equal to 2 V and does not exceed the breakdown voltage. This is the same with the other transistors. That is to say, voltage higher than the breakdown voltage is not applied to them.

At the timing t10 the voltage Vin of the signal inputted to the input buffer circuit 50 rises. At this time, the transistor 11 goes into an ON state and the voltage Vn2 at the node n2 and the voltage Vn3 at the node n3 rise. As indicated by equation (5), as the voltage Vin rises, potential at the source and the back gate of the transistor 11 (voltage Vn2 at the node n2) also rises. Accordingly, voltage higher than the breakdown voltage is not applied to the transistor 11 and the transistor 11 does not break down. Similarly, voltage higher than the breakdown voltage is not applied to the other transistors.

When the voltage Vin rises further and the voltage Vn2 at the node n2 becomes close to 1.8 V, the transistor 22 goes into an OFF state and the power supply voltage VDD3 (=3.3 V) applied to the gate of the transistor 21 becomes effective instead. Therefore, the voltage Vn1 at the node n1 can be indicated by equation (6) and rises to about 3.1 to 3.2 V. The voltage Vn2 also rises to about 3.0 to 3.1 V. As a result, even when the voltage Vin becomes 5 V, the potential difference between the gate and the source of the transistor 11, the potential difference between the gate and the drain of the transistor 11, and the potential difference between the gate and the back gate of the transistor 11 is smaller than or equal to 2 V and the transistor 11 does not break down.

Furthermore, even when the voltage Vn2 becomes about 3.1 to 3.2 V, the voltage Vn3 at the node n3 does not exceed the power supply voltage VDD2 (=1.8 V) applied to a gate of the transistor 12 because the source of the transistor 12 is connected to its back gate. In addition, as indicated in FIG. 4, the voltage Vn3 at the node n3 becomes about 1 V by the influence of a resistance component of the transistor 13 in an ON state. Accordingly, the transistors 14a and 14b included in the inverter circuit 14 and the transistors 15a and 15b included in the inverter circuit 15 do not break down either.

At timing t11 the voltage Vin begins to drop. At this time the voltage Vn1 and the voltage Vn2 also begin to drop. When the voltage Vn2 becomes close to 1.8 V, the transistor 22 goes into an ON state and the voltage Vn1 at the node n1 is fixed at about 1.8 V. Like the voltage Vin, the voltage Vn2 drops to 0 V.

At this time the potential difference between the gate and the source of the transistor 11, the potential difference between the gate and the drain of the transistor 11, and the potential difference between the gate and the back gate of the transistor 11 is smaller than or equal to 2 V. Similarly, voltage higher than the breakdown voltage is not applied to the other transistors.

As has been described, with the input buffer circuit 50 according to the second embodiment the voltage changing circuit portion 20 changes voltage applied to the drain, the source, or the back gate of the transistor 11 according to a change in the potential level of an input signal so that the potential difference between the gate and the source of the transistor 11, the potential difference between the gate and the drain of the transistor 11, or the potential difference between the gate and the back gate of the transistor 11 will not exceed the breakdown voltage of the transistor 11. This makes it possible to prevent the transistor 11 from breaking down. Adoption of the above circuit structure and voltage values makes it possible to prevent the other transistors from breaking down.

(Semiconductor Device)

The above input buffer circuit is applied to, for example, the following semiconductor device.

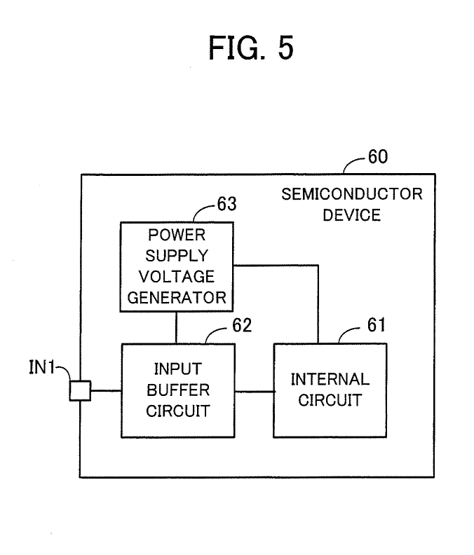

FIG. 5 is an example of a semiconductor device.

A semiconductor device 60 includes an internal circuit 61, an input buffer circuit 62, and a power supply voltage generator 63.

The input buffer circuit 62 is a circuit illustrated in FIG. 1 or 2.

The power supply voltage generator 63 generates power supply voltage and supplies it to the input buffer circuit 62 or the internal circuit 61. For example, the power supply voltage generator 63 generates the above three power supply voltages VDD1, VDD2, VDD3 and supplies them to the input buffer circuit 62.

When an input signal in which there is a comparatively great change in potential level (5 V or more, for example) is inputted from an input terminal IN1, the input buffer circuit 62 performs the above operation for generating a signal having a voltage of about 0 to 1 V, and supplies it to the internal circuit 61.

As a result, even if a low breakdown voltage transistor, such as a 1.8-volt transistor, is used in the input buffer circuit 62 or the internal circuit 61, it is possible to prevent it from breaking down.

According to the disclosed input buffer circuit and semiconductor device, it is possible to prevent a transistor from breaking down.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An input buffer circuit comprising:
a first transistor configured to receive an input signal at a first gate, a first drain or first source of the first transistor being connected to a first back gate of the first transistor; and
a voltage changing circuit portion configured to change a first voltage applied to the first drain or the first source in accordance with a change in potential level of the input signal so that a potential difference between the first gate and the first drain or the first source is lower than or equal to breakdown voltage of the first transistor.

2. The input buffer circuit of claim 1, further comprising:
a second transistor which is an n-channel transistor, a second drain of the second transistor being connected to the first source, a second back gate of the second transistor being connected to a second source of the second transistor; and
a third transistor, a third drain of the third transistor being connected to the second source, a third source and a third back gate of the third transistor being connected to a reference power supply line,
wherein:
the first transistor is an n-channel transistor;
a second voltage is applied to a second gate of the second transistor and a third gate of the third transistor, the second voltage being lower than or equal to breakdown voltage of the second transistor and breakdown voltage of the third transistor, the second voltage putting the second transistor and the third transistor into an ON state; and
a node between the second source and the third drain is connected to a circuit portion at a subsequent stage.

3. The input buffer circuit of claim 2, wherein:
the voltage changing circuit portion includes a fourth transistor which is an n-channel transistor and a fifth transistor which is a p-channel transistor;
a third voltage which puts the fourth transistor into an ON state is applied to a fourth drain and a fourth gate of the fourth transistor and a fourth source of the fourth transistor is connected to a fourth back gate of the fourth transistor and the first drain; and
a fourth voltage lower than the first voltage is applied to a fifth source and a fifth back gate of the fifth transistor, a fifth gate of the fifth transistor is connected to the first back gate and the first source, and a fifth drain of the fifth transistor is connected to the first drain.

4. The input buffer circuit of claim 3, wherein the fifth transistor is larger in size than the fourth transistor.

5. The input buffer circuit of claim 3, wherein when both of the fourth transistor and the fifth transistor go into an ON state, potential of the first drain becomes equal to potential corresponding to the second voltage.

6. A semiconductor device comprising:
an internal circuit; and
an input buffer circuit including:
a first transistor configured to receive at a first gate an input signal inputted from an outside to the internal circuit, a first drain or first source of the first transistor being connected to a first back gate of the first transistor; and
a voltage changing circuit portion configured to change a first voltage applied to the first drain or the first source in accordance with a change in potential level of the input signal so that a potential difference between the first gate and the first drain or the first source is lower than or equal to breakdown voltage of the first transistor.

7. The semiconductor device of claim 6, wherein:
the first transistor is an n-channel transistor;
the input buffer circuit further includes:
a second transistor which is a n-channel transistor, a second drain of the second transistor being connected to the first source, a second back gate of the second transistor being connected to a second source of the second transistor; and
a third transistor, a third drain of the third transistor being connected to the second source, a third source and a third back gate of the third transistor being connected to a reference power supply line;
a second voltage is applied to a second gate of the second transistor and a third gate of the third transistor, the second voltage being lower than or equal to breakdown voltage of the second transistor and breakdown voltage of the third transistor, the second voltage putting the second transistor and the third transistor into an ON state; and
a node between the second source and the third drain is connected to a circuit portion at a subsequent stage.

8. The semiconductor device of claim 7, wherein:
the voltage changing circuit portion includes a fourth transistor which is an n-channel transistor and a fifth transistor which is a p-channel transistor;
a third voltage which puts the fourth transistor into an ON state is applied to a fourth drain and a fourth gate of the fourth transistor and a fourth source of the fourth transistor is connected to a fourth back gate of the fourth transistor and the first drain; and
a fourth voltage lower than the first voltage is applied to a fifth source and a fifth back gate of the fifth transistor, a fifth gate of the fifth transistor is connected to the first back gate and the first source, and a fifth drain of the fifth transistor is connected to the first drain.

9. The semiconductor device of claim 8, wherein the fifth transistor is larger in size than the fourth transistor.

10. The semiconductor device of claim 8, wherein when both of the fourth transistor and the fifth transistor go into an ON state, potential of the first drain becomes equal to potential corresponding to the second voltage.
